(19) United States
(12) Patent Application Publication
(10) Pub. No.: US 2006/0113551 A1
(43) Pub. Date: Jun. 1, 2006

(54) Pixel circuit and light emitting display

(76) Inventor: Won Kyu Kwak, Seongnam (KR)

Correspondence Address: CHRISTIE, PARKER & HALE, LLP, PO BOX 7068, PASADENA, CA, 91109-7068, US

(21) Appl. No.: 11/274,940

(22) Filed: Nov. 14, 2005

(30) Foreign Application Priority Data
Nov. 22, 2004 (KR) 10-2004-0095977

(51) Int. Cl. H01L 33/00

(52) U.S. Cl. 257/85

(57) ABSTRACT

A light emitting display includes a plurality of scan lines, a plurality of data lines, a plurality of first light emitting control lines, a plurality of second light emitting controls lines, a plurality of third light emitting control lines, and a plurality of pixels. Each of the pixels includes at least four light emitting elements, a drive circuit, connected to and driving the light emitting elements, and a switch circuit assembly, connected to the light emitting elements and the drive circuit for sequentially controlling driving of the light emitting elements. The switch circuit assembly includes a first switch circuit, for sequentially driving the first and second light emitting elements according to first and second light emitting control signals, and a second switch circuit, for sequentially driving the third and fourth light emitting elements according to second and third light emitting control signals.

### CROSS-REFERENCE TO RELATED APPLICATION

This application claims priority to and the benefit of Korean Patent Application No. 10-2004-95977, filed on Nov. 22, 2004, in the Korean Intellectual Property Office, the entire disclosure of which is incorporated herein by reference.

### BACKGROUND

a) Field of the Invention

The present invention relates to a pixel circuit and a light emitting display, and more particularly, to a pixel circuit and a light emitting display using the same, which emits light by a plurality of light emitting elements connected to one pixel circuit in order to improve the aperture ratio of the light emitting display.

b) Discussion of Related Art

In recent years, various display devices having reduced weight and volume compared to those of a cathode ray tube have been developed. In particular, light emitting displays having excellent light-emission, a wide angle of visibility, and a high-speed response have been proposed as next-generation planar type display devices.

A light emitting element has a structure in which a light emitting layer is disposed between a cathode electrode and an anode electrode. Electrons and holes are injected from the cathode electrode and the anode electrode into the light emitting layer and are recombined to produce an exciton. When the exciton falls to a lower energy level, light is emitted.

In such a light emitting element, the light emitting layer may be composed of organic materials or inorganic materials. The light emitting element may be an organic light emitting element or an inorganic light emitting element, according to its material and structure.

FIG. 1 is a circuit diagram showing a part of an image display device in which a current write-type pixel circuit is used. Referring to FIG. 1, the image display device includes four pixels formed adjacent to each other. Each of the pixels includes an organic light emitting diode (OLED) and a pixel circuit. The pixel circuit includes a first transistor T1 through a third transistor T3, and a capacitor Cst. Each of the first through third transistors T1 through T3 includes a gate, a source, and a drain. The capacitor Cst includes a first electrode and a second electrode.

The four pixels have the same structure. In an upper-most left pixel, a source of a first transistor T1 is connected to a power supply line Vdd, a drain thereof is connected to a source of a third transistor T3, and a gate thereof is connected to a first node A. The first node A is connected to a drain of a second transistor T2. The first transistor T1 supplies a current corresponding to a data signal to a light emitting element OLED.

A source of the second transistor T2 is connected to a data line D1, a drain thereof is connected to the first node A, and a gate thereof is connected to a first scan line S1. The second transistor T2 transfers the data signal to the first node A according to a scan signal applied to a gate thereof.

A source of the third transistor T3 is connected to a drain of the first transistor M1, a drain thereof is connected to an anode electrode of the light emitting element OLED, a gate thereof is connected to a light emitting control line E1. The third transistor operates according to a light emitting control signal. Accordingly, the conventional light emitting display controls a flow of a current flowing from the first transistor T1 to the light emitting element OLED in order to control light emission of the light emitting element OLED.

A first electrode of the capacitor Cst is connected to the power supply line Vdd, and a second electrode thereof is connected to the first node A. The capacitor Cst stores an electric charge according to the data signal, and applies a signal to a gate of the first transistor T1 according to the electric charge for one frame period, thereby maintaining an operation of the first transistor T1 for one frame period.

However, in a conventional pixel in which a light emitting display is used, one OLED is connected to one pixel circuit. In order to emit a plurality of light emitting elements, a plurality of pixel circuits are needed. Thus, the conventional light emitting display has a problem in that the number of elements required for use of a light emitting display may be high.

Moreover, because one light emitting control line is connected to each pixel row, the aperture ratio of a light emitting display may be deteriorated.

### SUMMARY OF THE INVENTION

Accordingly, it is an aspect of the present invention to provide a pixel circuit and a light emitting display, which reduce the number of elements, increase the aperture ratio, and minimize color breakup in the light emitting display by connecting a plurality of light emitting elements to one pixel circuit.

The foregoing and/or other aspects of the present invention are achieved by providing a light emitting display including a plurality of scan lines, a plurality of data lines, a plurality of first light emitting control lines, a plurality of second light emitting control lines, a plurality of third light emitting control lines, and a plurality of pixels. Each of the pixels includes a first light emitting element, a second light emitting element, a third light emitting element, and a fourth light emitting element. A drive circuit is connected to and drives the first through fourth light emitting elements, and a switch circuit assembly is connected between the first through fourth light emitting elements and the drive circuit for sequentially controlling driving of the first through fourth light emitting elements. The switch circuit assembly includes a first switch circuit, for sequentially driving the first and second light emitting elements according to first and second light emitting control signals, and a second switch circuit, for sequentially driving the third and fourth light emitting elements according to second and third light emitting control signals.

According to another aspect of the present invention, there a pixel circuit includes a first transistor for generating a current according to a first voltage corresponding to a data signal, a second transistor for transferring the data signal corresponding to the scan signal to the first transistor, and a capacitor for storing the first voltage for a predetermined time. The pixel circuit may also include a third transistor for transferring a current according to a first light emitting control signal, a fourth transistor for transferring the current transferred by the third transistor to the first light emitting element according to a third light emitting control signal, a fifth transistor for maintaining a state different from the fourth transistor according to the third light emitting control signal and for transferring the current transferred by the third transistor to a second light emitting element, a sixth transistor for transferring the current according to a second light emitting control signal, a seventh transistor for transferring the current transferred by the sixth transistor to a third light emitting element according to the third light emitting control signal, and an eighth transistor for maintaining a state different from the seventh transistor according to the third light emitting control signal and for transferring the current transferred by the seventh transistor to a fourth light emitting element.

According to a third aspect of the present invention, there is provided a pixel circuit including a first transistor for generating a current according to a first voltage corresponding to a data signal, a second transistor for transferring the data signal corresponding to a first scan signal to the first transistor, and a first capacitor for storing the first voltage for a predetermined time. A second capacitor stores a threshold voltage of the second transistor, and a third transistor diode-connects the first transistor according to a second scan signal. A fourth transistor transfers voltage to a first electrode of the second capacitor according to a second scan signal, and a fifth transistor transfers a current according to a first light emitting control signal. A sixth transistor transfers the current transferred by the fifth transistor to the first light emitting element according to a third light emitting control signal. A seventh transistor maintains a state different from the sixth transistor according to the third light emitting control signal and transfers the current transferred by the sixth transistor to a second light emitting element. An eighth transistor for transfers a current according to a second light emitting control signal, and a ninth transistor transfers the current transferred by the eighth transistor to a third light emitting element according to the third light emitting control signal. A tenth transistor maintains a state different from the ninth transistor according to the third light emitting control signal and transfers the current transferred by the eighth transistor to a fourth light emitting element.

### BRIEF DESCRIPTION OF THE DRAWINGS

These and/or other aspects and features of the invention will become apparent and more readily appreciated from the following description of examples of embodiments, taken in conjunction with the accompanying drawings of which:

FIG. 1 is a circuit diagram showing a part of a conventional image display device;

FIG. 2 is a schematic view showing a structure of a light emitting display according to a first embodiment of the present invention;

FIG. 3 is a schematic view showing a structure of a light emitting display according to a second embodiment of the present invention;

FIG. 4 is circuit diagram showing a first example of a pixel used in the light emitting display of FIG. 2;

FIG. 5 is a waveform of signals transferred to a light emitting display in which the pixel of FIG. 4 is used;

FIG. 6 is circuit diagram showing a first example of a pixel used in the light emitting display of FIG. 3;

FIG. 7 is a waveform of signals transferred to a light emitting display in which the pixel circuit of FIG. 6 is used; and

FIGS. 8A through 8D are views showing light emitting process of the light emitting display of FIG. 3.

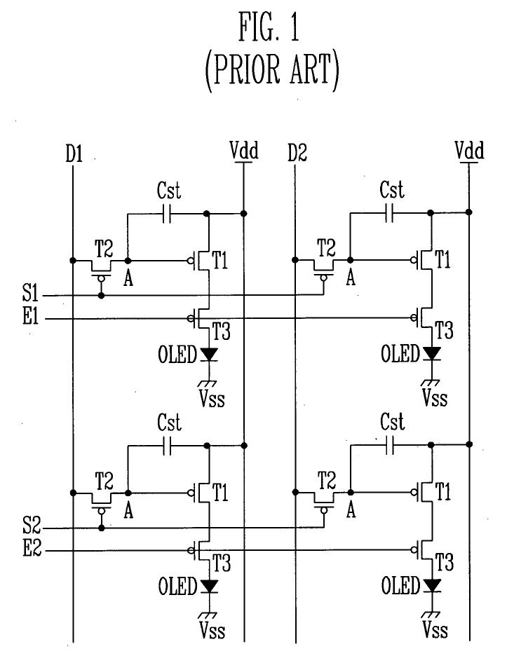

### DETAILED DESCRIPTION

Hereinafter, examples of embodiments according to the present invention will be described with reference to the accompanying drawings. Elements described as connected directly to another element may alternatively be connected through one or more intervening elements. Like reference numerals refer to like elements, and descriptions of common elements that are well-known in the art are omitted for clarity.

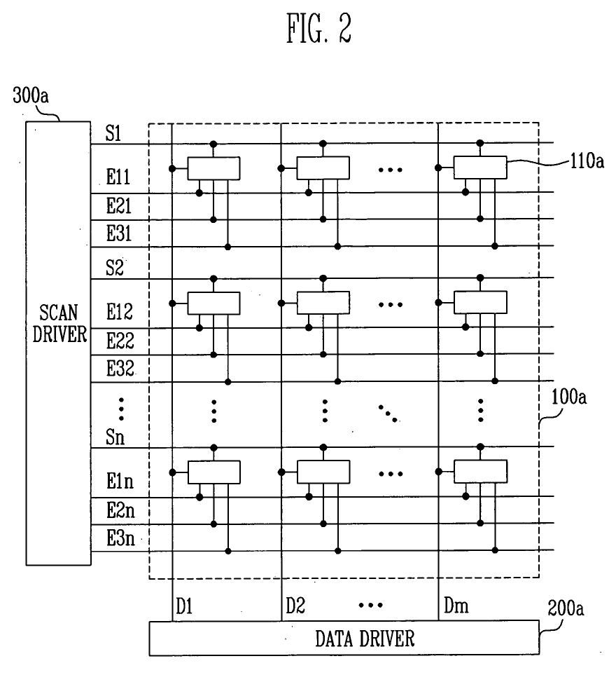

FIG. 2 is a schematic view showing a structure of a light emitting display according to a first embodiment of the present invention. With reference to FIG. 2, the light emitting display includes an image display device 100a, a data driver 200a, and a scan driver 300a.

The image display device 100a includes a plurality of pixels 110a, a plurality of scan lines S1, S2, S3 . . . Sn−1, Sn, a plurality of first light emitting control lines E11, E12 . . . E1n−1, E1n, a plurality of second light emitting control lines E21, E22, . . . E2n−1, E2n, and third light emitting control lines E31, E32, . . . . E3n−1, E3n are arranged along a column direction. The device also includes a plurality of data lines D1, D2 . . . Dm−1, Dm arranged in a row direction, and a plurality of pixel power lines (not shown) for supplying power to the pixels. Each of the power lines receives external power and supplies it to the pixels.

When a data signal is transferred to a circuit of a pixel 110a through the scan lines S1, S2, S3 . . . Sn−1, Sn and data lines D1, D2, . . . Dm−1, Dm according to a scan signal, the circuit of a pixel 110a generates a drive current corresponding to the data signal. The drive current is transferred to an OLED according to a light emitting control signal transferred through the first light emitting control lines E11, E12, . . . E1n−1, E1n through the third light emitting control lines E31, E32, . . . E3n−1, E3n to display an image.

The data driver 200a is connected to the data lines D1, D2 . . . Dm−1, Dm, and transfers the data signal to the image display device 100a. Further, the data driver 200a sequentially transfers red and green data, green and blue data, or blue and red data on one data line.

The scan driver 300a is installed at a side of the image display device 100a. The scan driver 300a is connected to a plurality of scan lines S1, S2, S3 . . . Sn−1, Sn, a plurality of first light emitting control lines E11, E12, . . . E1n−1, E1n, through a plurality of third light emitting control lines E31, E32 . . . E3n−1, E3n, and sequentially transfers scan signals and light emitting control signals to the image display device 100a.

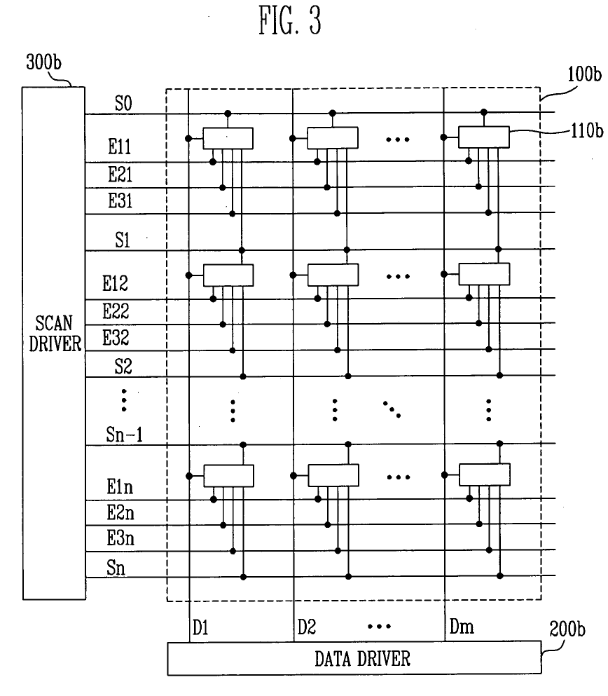

FIG. 3 is a schematic view showing a structure of a light emitting display according to a second embodiment of the present invention. With reference to FIG. 3, the light emitting display includes an image display device 100b, a data driver 200b, and a scan driver 300b.

The image display device 100b includes a plurality of pixels 110b, a plurality of scan lines S0, S1, S2, S3 . . . . Sn−1, Sn, a plurality of first light emitting control lines E11, E12, . . . E1n−1, E1n, a plurality of second light emitting control lines E21, E22, . . . . E2n−1, E2n, a plurality of third light emitting control lines E31, E32, . . . . E3n−1, E3n all arranged along a column direction. The device also includes a plurality of data lines D1, D2, . . . . Dm−1, Dm arranged in a row direction, and a plurality of pixel power lines (not shown) for supplying power to the pixels. Each of the power lines receives an external power and supplies power to the pixels.

Each pixel 110b receives scan signals of a scan line and a previous scan line through the scan lines S0, S1, S2, S3, . . . Sn−1, Sn, and generates a drive current corresponding to a data signal transferred to the data lines D1, D2, . . . Dm−1, Dm. The drive current is transferred to a light emitting element OLED according to a light emitting control signal transferred through the first light emitting control lines E11, E12 . . . E1n−1, E1n to the third light emitting control lines E31, E32, . . . E3n−1, E3n, thereby displaying an image.

The data driver 200b is connected to the data lines D1, D2, . . . Dm−1, Dm, and transfers the data signal to the image display device 100b. Further, the data driver 200b sequentially transfers red and green data, green and blue data, or blue and red data to one data line.

The scan driver 300b is installed at a side of the image display device 100b. The scan driver 300b is connected to a plurality of scan lines S1, S2, S3, . . . Sn−1, Sn, a plurality of first light emitting control lines E11, E12 . . . E1n−1, E1n, through a plurality of third light emitting control lines E31, E32, . . . E3n−1, E3n, and sequentially transfers scan signals and light emitting control signals to the image display device 100b.

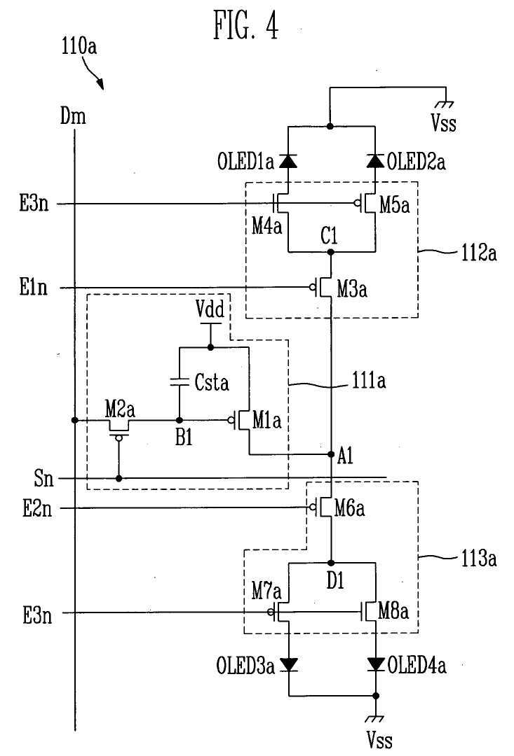

FIG. 4 is circuit diagram showing a first example of a pixel used in the light emitting display shown in FIG. 2. With reference to FIG. 4, the pixel 110a includes a light emitting element and a pixel circuit. Four OLEDs are connected to one pixel circuit. Each pixel circuit includes first through eighth transistors M1a through M8a, and a capacitor Csta.

The pixel circuit is divided into a drive circuit 111a, a first switch circuit 112a, and a second switch circuit 113a. The drive circuit 111a includes the first and second transistors M1a and M2a, and a capacitor Csta. The first switch circuit 112a includes the third through fifth transistors M3a through M5a. The second switch circuit 113a includes the sixth through eighth transistors M6a through M8a.

Each of the first through eighth transistors M1a through M8a includes a source, a drain, and a gate. In this embodiment, the first through third transistors M1a through M3a and the fifth through seventh transistors M5a through M7a are PMOS transistors. The fourth and eighth transistors M4a and M8a are NMOS transistors. Since each source and drain of the first through eighth transistors M1a through M8a have the same physical characteristics, the source and drain can be called first and second electrodes, respectively. Further, the capacitor Csta includes first and second electrodes. Four light emitting elements are called first through fourth light emitting elements OLED1a through OLED4a.

A source of the first transistor M1a is connected to a pixel power line Vdd, a drain thereof is connected to a first node A1, and a gate thereof is connected to a second node B1. The first transistor M1a determines the amount of drive current flowing from the source thereof to the drain according to a voltage applied to the gate thereof.

A source of the second transistor M2a is connected to a data line Dm, a drain thereof is connected to the second node B1, and a gate thereof is connected to a scan line Sn. The second transistor M2a performs an on/off operation according to a scan signal transferred through the scan line Sn, and provides a data signal to the second node B1.

A source of the third transistor M3a is connected to the first node A1, a drain thereof is connected to the third node C1, and a gate thereof is connected to the first light emitting control line E1n. The third transistor M3a performs an on/off operation according to the first light emitting control signal e1n received through the first light emitting control line E1n, and allows a drive current to flow into the first node A1, from the source of the third transistor M3a to the drain thereof.

A source of the fourth transistor M4a is connected to the third node C1, a drain thereof is connected to the first light emitting element OLED1a, and a gate thereof is connected to the third light emitting control line E3n. The fourth transistor M4a transfers a current flowing from the source of the fourth transistor M4a to the drain thereof to the first light emitting element OLED1a according to a third light emitting control signal e3n transferred through the third light emitting control line E3n, which allows the first light emitting element OLED1a to emit light.

A source of the fifth transistor M5a is connected to the third node C1, a drain thereof is connected to the second light emitting element OLED2a, and a gate thereof is connected to a third light emitting control line E3n. The fifth transistor M5a transfers a drive current flowing from the source of the fifth transistor M5a to the drain thereof to a second light emitting element OLED2a according to a third light emitting control signal e3n transferred through the third light emitting control line E3n, which allows the second light emitting element OLED2a to emit light

A source of the sixth transistor M6a is connected to the first node A1, a drain thereof is connected to the fourth node D1, and a gate thereof is connected to a second light emitting control line E2n. The sixth transistor M6a performs an on/off operation according to a second light emitting control signal e2n supplied through the second light emitting control line E2n, and allows a current to flow into the first node A1, from the source of the sixth transistor M6a to the drain thereof.

A source of the seventh transistor M7a is connected to the fourth node D1, a drain thereof is connected to the third light emitting element OLED3a, and a gate thereof is connected to the third light emitting control line E3n. The seventh transistor M7a transfers a current flowing from the source of the seventh transistor M7a to the drain thereof to a third light emitting element OLED3a according to the third light emitting control signal e3n supplied through the third light emitting control line E3n, which allows the third light emitting element OLED3a to emit light.

A source of the eighth transistor M8a is connected to the fourth node D1, a drain thereof is connected to the fourth light emitting element OLED4a, and a gate thereof is connected to the third light emitting control line E3n. The eighth transistor M8a transfers a current flowing from the source of the eighth transistor M8a to the drain thereof to a fourth light emitting element OLED4a according to the third light emitting control signal e3n supplied through the third light emitting control line E3n, which allows the fourth light emitting element OLED4a to emit light.

The fourth transistor M4a is an NMOS transistor, and the fifth transistor M5a is a PMOS transistor. The third light emitting control signal e3n controls one of the fourth transistor M4a and the fifth transistor M5a to be turned on, so either the first or second light emitting element OLED1a, OLED2a emits light.

The seventh transistor M7a is a PMOS transistor, and the eighth transistor M8a is an NMOS transistor. The third light emitting control signal e3n controls one of the seventh transistor M7a and the eighth transistor M8a to be turned on, so either the third or fourth light emitting element OLED3a, OLED4a emits light.

The first electrode of the first capacitor Csta is connected to the pixel power line Vdd, and the second electrode thereof is connected to the second node B1. The first capacitor Csta stores a voltage corresponding to a difference between a voltage of the pixel power line Vdd and a voltage of the second node B1, and transfers the voltage to the gate of the first transistor M1a for a predetermined time.

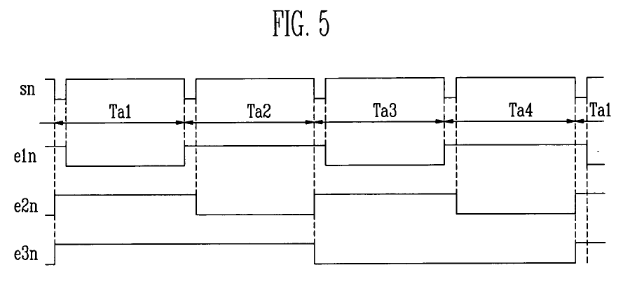

FIG. 5 is a waveform of signals transferred to a light emitting display in which the pixel 110a of FIG. 4 is used. Referring to FIG. 5, the pixel operates according to a scan signal sn, a data signal, and first through third light emitting control signals e1n through e3n. The scan signal sn and first through third light emitting control signals e1n through e3n are period signals, and repeat in the first through fourth periods Ta1 through Ta4.

During a first period Ta1, the first light emitting control signal e1n is in a low state, and the second and third light emitting control signals e2n and e3n are in a high state. During a second period Ta2, the first and third light emitting control signals e1n and e3n are in a high state, and the second light emitting control signal e2n is in a low state. During a third period Ta3, the first and third light emitting control signals e1n and e3n are in a low state, and the second light emitting control signal e2n is in a high state. In addition, during a fourth period T4a, the first light emitting control signal e1n is in a high state, and the second and third light emitting control signals e2n and e3n are in a low state. A scan signal sn is in a low state for a moment at a start point of each period.

Referring again to FIGS. 4 and 5, during the first period Ta1, the second transistor M2a is turned on according to the scan signal sn to cause a data signal to be transferred to the second node B1 through the second transistor M2a. Further, pixel power is transferred to the first electrode of the capacitor Csta to store a voltage corresponding to a difference Vdd−Vdata in voltage between the pixel power and the data signal in the capacitor Csta.

The capacitor Csta applies the voltage corresponding to a difference Vdd−Vdata between the pixel power and the data signal to the gate of the first transistor M1a, which allows the first transistor M1a to allow current to flow that corresponds to the data signal applied to the first node A1.

Further, the third transistor M3a is turned on according to the first light emitting control signal e1n, and the sixth transistor M6a is turned off according to the second light emitting control signal e2n, thereby causing the current flowing in the first node A1 to flow into the third node C1. The fourth transistor M4a is turned on and the fifth transistor M5a is turned off according to the third light emitting control signal e3n, thereby causing the current to flow through the first light emitting element OLED1a.

During the second period Ta2, a voltage corresponding to a difference between the voltage of the pixel power and the data signal is stored in the capacitor Csta according to the scan signal sn and the data signal. The first transistor M1a allows a drive current corresponding to the data signal to flow into the first node A1. In addition, the third transistor M3a is turned off according to the first light emitting control signal e1n, and the sixth transistor M6a is turned on according to the second light emitting control signal e2n, which causes a current to flow into the fourth node D1. Further, the eighth transistor M8a is turned on and the seventh transistor M7a is turned off according to the third light emitting control signal e3n, which causes current to flow through the fourth light emitting element OLED4a.

A third period Ta3 and a fourth period Ta4 generate the same current as that of the first period Ta1 and the second period Ta2. During the third period Ta3, the third transistor M3a is turned on and the sixth transistor M6a is turned off according to the first light emitting control signal e1n and the second light emitting control signal e2n, causing current to flow into the third node C1. The fifth transistor M5a is turned on and the fourth transistor M4a is turned off according to the third light emitting control signal e3n, which allows the current to flow through the second light emitting element OLED2a. During the fourth period T4, the third transistor M3a is turned off and the sixth transistor M6a is turned on according to the first light emitting control signal e1n and the second light emitting control signal e2n, causing current to flow into the fourth node D1. The seventh transistor M7a is turned on and the eighth transistor M8a is turned off according to the third light emitting control signal e3n, which allows current to flow through the third light emitting element OLED3a. Consequently, the first through fourth light emitting elements OLED1a through OLED4a sequentially emit light.

FIG. 6 is a circuit diagram showing a first example of a pixel used in the light emitting display shown in FIG. 3. With reference to FIG. 6, the pixel includes a light emitting element and a pixel circuit. Four light emitting elements OLEDs are connected to one pixel circuit. Each pixel circuit 110b includes first through tenth transistors M1b through M10b, a first capacitor Cstb and a second capacitor Cvthb.

Further, the pixel circuit can be divided into a drive circuit 111b, a first switch circuit 112b, and a second switch circuit 113b. The drive circuit 111b includes first through fourth transistors M1b through M4b, and first and second capacitors Cstb and Cvthb. The first switch circuit 112b includes fifth to seventh transistors M5b to M7b. The second switch circuit 113b includes eighth to tenth transistors M8b to M10b.

Each of the first to tenth transistors M1b to M10b includes a source, a drain, and a gate. In this embodiment, the first to fifth transistors M1b to M5b, and the seventh to ninth transistors M7b to M9b are PMOS transistors. The sixth transistor M6b and the tenth transistor M10b are NMOS transistors. Since each source and drain of the first through tenth transistors M1b through M10b have the same physical characteristics, the source and drain thereof can be called first and second electrodes, respectively. Each of the first and second capacitors Cstb and Cvthb includes a first electrode and a second electrode. Four light emitting elements are designated as the first to fourth light emitting elements OLED1b to OLED4b.

A source of the first transistor M1b is connected to a pixel power line Vdd, a drain thereof is connected to a first node A2, and a gate thereof is connected to a second node B2. The first transistor M1b determines an amount of a drive current to flow from the source to the drain according to a voltage applied to the gate thereof.

A source of the second transistor M2b is connected to a data line Dm, a drain thereof is connected to the third node C2, and a gate thereof is connected to a scan line Sn. The second transistor M2b performs an on/off operation according to a first scan signal sn transferred through a first scan line Sn, and selectively transfers a data signal to the third node C2.

A source of the third transistor M3b is connected to a first node A2, a drain thereof is connected to the second node B2, and a gate thereof is connected to a second scan line Sn−1. The third transistor M3b performs an on/off operation according to a second scan signal sn−1 transferred through the second scan line Sn-1, which causes the first and second nodes A2 and B2 to have the same electric potential. As a result, the first transistor M1b is selectively diode-connected.

A source of the fourth transistor M4b is connected to the pixel power line Vdd, a drain thereof is connected to the third node C2, and a gate thereof is connected to a second scan line Sn−1. The fourth transistor M4b sequentially transfers pixel power to the third node C2 according to a second scan signal sn−1.

A source of the fifth transistor M5b is connected to the first node A2, a drain thereof is connected to the fourth node D2, and a gate thereof is connected to a first light emitting control line E1n. The fifth transistor M5b carries out on/off operation according to a first light emitting control signal e1n transferred through the first light emitting control line E1n, thereby causing a current that is flowing into the first node A2 to flow into the fourth node D2.

A source of the sixth transistor M6b is connected to the fourth node D2, a drain thereof is connected to the first light emitting element OLED1b, and a gate thereof is connected to a third light emitting control line E3n. The sixth transistor M6b transfers a current that is flowing into the fourth node D2 to the first light emitting element OLED1b according to a third light emitting control signal e3n transferred through the third light emitting control line E3n, which allows the first light emitting element OLED1b to emit light.

A source of the seventh transistor M7b is connected to the fourth node D2, a drain thereof is connected to the second light emitting element OLED2b, and a gate thereof is connected to the third light emitting control line E3n. The seventh transistor M7b transfers a current flowing into the fourth node D2 to the second light emitting element OLED2b according to the third light emitting control signal e3n supplied through the third light emitting control line E3n, which allows the second light emitting element OLED2b to emit light.

A source of the eighth transistor M8b is connected to the first node A2, a drain thereof is connected to the fifth node E2, and a gate thereof is connected to the second light emitting control line E2n. The eighth transistor M8b carries out on/off operation according to a second light emitting control signal e2n transferred through the second light emitting control line E2n, thereby causing a current flowing into the first node A, to flow into the fifth node E2.

A source of the ninth transistor M9b is connected to the fifth node E2, a drain thereof is connected to the third light emitting element OLED3b, and a gate thereof is connected to the third light emitting control line E3n. The ninth transistor M7b transfers a current flowing into the fifth node E2 to the third light emitting element OLED3b according to the third light emitting control signal e3n supplied through the third light emitting control line E3n, which allows the third light emitting element OLED3b to emit light.

A source of the tenth transistor M10b is connected to the fifth node E2, a drain thereof is connected to the fifth light emitting element OLED4b, and a gate thereof is connected to the third light emitting control line E3n. The tenth transistor M10b transfers a current flowing into the fifth node E2 to the fourth light emitting element OLED4b according to the third light emitting control signal e3n supplied through the third light emitting control line E3n, which allows the fourth light emitting element OLED4b to emit light.

The sixth transistor M6b is an NMOS transistor, and the seventh transistor M7b is a PMOS transistor. The third light emitting control signal e3n controls one of the sixth transistor M6b and the seventh transistor M7b to be turned on, so that selective one of the first and second light emitting elements OLED1b and OLED2b emits light.

The ninth transistor M9b is a PMOS transistor, and the tenth transistor M10b is an NMOS transistor. The third light emitting control signal e3n controls one of the ninth transistor M9b and the tenth transistor M10b to be turned on, so that selective one of the third and fourth light emitting elements OLED3b and OLED4b emits light.

The first electrode of the first capacitor Cstb is connected to the pixel power line Vdd, and the second electrode thereof is connected to the third node C2. The first capacitor Cstb stores a voltage corresponding to a difference between a voltage of the pixel power line Vdd and a voltage of the third node C2 by the fourth transistor M4.

The first electrode of the second capacitor Cvthb is connected to the third node C2, and the second electrode thereof is connected to the second node B2. The second capacitor Cvthb stores a voltage corresponding to a difference between a voltage of the second node B2 and a voltage of the third node C2.

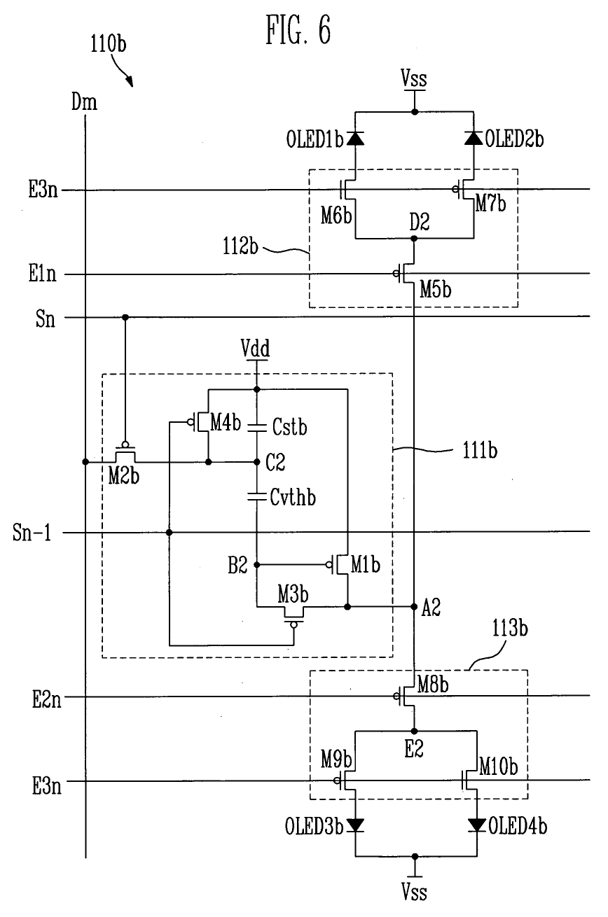

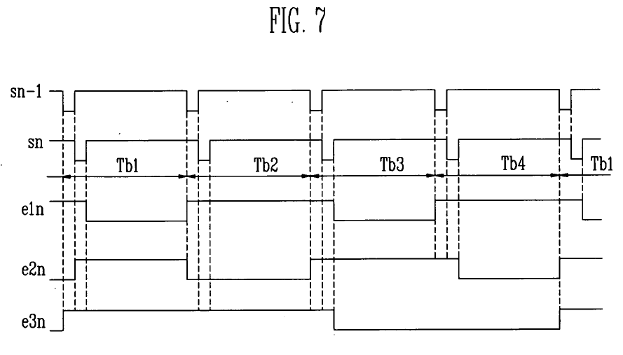

FIG. 7 is a waveform view of signals transferred to a light emitting display in which the pixel circuit of FIG. 6 is used. Referring to FIGS. 6 and 7, the pixel operates according to first and second scan signals sn and sn−1, a data signal, and first through third light emitting control signals e1[n] through e3[n]. The first and second scan signal sn and sn−1, and first through third light emitting control signals e1[n] through e3[n] are period signals, and repeat first through fourth periods Tb1 through Tb4.

During a first period Tb1, the first light emitting control signal e1n is in a low state, and the second and third light emitting control signals e2n and e3n are in a high state. During a second period Tb2, the first and third light emitting control signals e1n and e3n are in a high state, and the second light emitting control signal e2n is in a low state. During a third period Tb3, the first and third light emitting control signals e1n and e3n are in a low state, and the second light emitting control signal e2n is in a high state.

In addition, during a fourth period Tb4, the first light emitting control signal e1n is in a high state, and the second and third light emitting control signals e2n and e3n are in a low state. The second scan signal sn−1 is a scan signal of a scan line prior to the first scan signal sn. The first and second scan signals sn and sn−1 are in a low state for a moment in order at a start point of each period.

During the first period Tb1, the third transistor M3b and the fourth transistor M4b are turned on according to the second scan signal sn−1, so that the first transistor M1b is diode-connected and a pixel power is transferred to a first electrode of the second capacitor Cvthb. At this time, a voltage corresponding to a difference between the pixel power and a threshold voltage of the first transistor M1b is applied to the second node B2, thereby causing a voltage corresponding to the threshold voltage of the first transistor M1b to be stored in the second capacitor Cvthb.

In addition, when the second transistor M2b is turned on according to the first scan signal sn, a data signal is transferred to the third node C2, thus transferring a pixel power and the data signal to the first and second electrodes of the first capacitor Cstb, respectively. This causes a voltage corresponding to a difference Vdd-Vdata between the pixel power and the data signal to be stored in the first capacitor Cstb.

By the first capacitor Cstb and the second capacitor Cvthb connected to each other in series, a voltage expressed by a following equation 1 is applied between the source and the gate of the first transistor M1b.
Vgs=Vdd−(Vdata−Vth) (1)
where, Vgs is a voltage between a source and a gate of the first transistor M1b, Vdata is a voltage of the data signal, Vth is a threshold voltage of the first transistor M1b.

Accordingly, a current flowing from a source of the first transistor M1b to a drain thereof is expressed by a following equation 2.
I=β/2(Vgs−Vth)²=β/2(Vdd−(Vdata−Vth)−Vth)²=β/2(Vdd−Vdata)² (2)
where, Vgs is a voltage between a source and a gate of the first transistor M1b, Vdd is a voltage of a pixel power supply, Vdata is a voltage of the data signal, Vth is a threshold voltage of the first transistor M1b, and β is a gain factor of the first transistor M1b.

Consequently, a current flowing from the source of the first transistor M1b to the drain thereof, flows regardless of a threshold voltage of the first transistor M1b. As a result, a current in which the threshold voltage is compensated, flows into the first node A2.

Further, the fifth transistor M5b is turned on according to the first light emitting control signal e1n and the eighth transistor M8b is turned off according to the second light emitting control signal e2n, thereby causing a current that is flowing into the first node A2 to flow into the fourth node D2. The sixth transistor M6b is turned on and the seventh transistor M7b is turned off according to the third light emitting control signal e3n, thereby causing the current to flow through the first light emitting element OLED1b.

During the second period Tb2, a voltage corresponding to a difference between the pixel power and the data signal is stored in the first capacitor Cstb according to the first and second scan signals sn and sn−1, and the data signal. The threshold voltage of the first transistor M1b is stored in the second capacitor Cvthb. This causes a current expressed by the equation 2 to flow from the first transistor M1b into the first node A2. Moreover, the fifth transistor M5b is turned off and the eighth transistor M8b is turned on according to the first light emitting control signal e1n and the second light emitting control signal e1n, thereby causing the current the is flowing into the first node A2 to flow into the fifth node E2. In addition, the ninth transistor M9b is turned off and the tenth transistor M10b is turned on according to the third light emitting control signal e3n. A drive current thus flows through the fourth light emitting element OLED4b.

During the third period Tb3 and the fourth period Tb4, as during the first period Tb1 and the second period Tb2, current flows into the first node A2. During the third period Tb3, the fifth transistor M5b is turned on and the eighth transistor M8b is turned off according to the first and second light emitting control signals e1n and e2n, thereby causing the current that is flowing into the first node A2 to flow into the fourth node D2. The sixth transistor M6b is turned off and the seventh transistor M7b is turned on according to the third light emitting control signal e3n, thereby causing the current to flow through the second light emitting element OLED2b. During the fourth period Tb4, the fifth transistor M5b is turned off and the eighth transistor M8b is turned on according to the first and second light emitting control signals e1n and e2n, thereby causing the current that is flowing into the first node A2 to flow into the fifth node E2. The ninth transistor M9b is turned on and the tenth transistor M10b is turned off according to the third light emitting control signal e3n, thereby causing the current to flow through the third light emitting element OLED3b. As a result, the first through fourth light emitting elements OLED1b through OLED4b sequentially emit light.

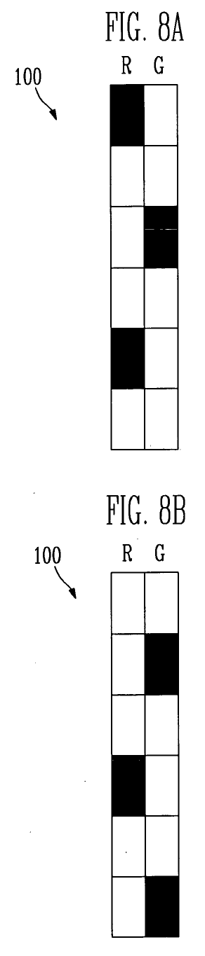

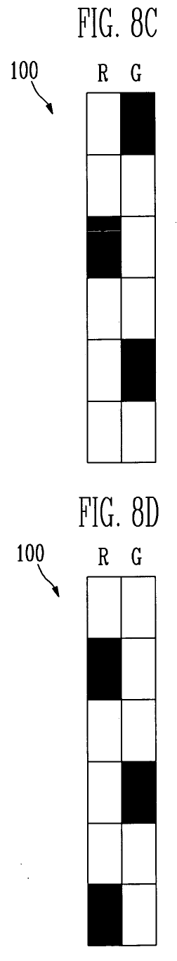

FIGS. 8A through 8D are views showing light emitted by a light emitting display having three circuits similar to the circuit shown in FIG. 6. An image display device 100 includes 3 such vertically arranged pixel circuits in which 12 light emitting elements are arranged in 2×6 form. In this embodiment, an upper pixel circuit is a first pixel circuit which is shown in FIG. 6, a middle pixel circuit is a second pixel circuit substantially the same as the first pixel circuit but with reversed polarity, and a lower pixel circuit is a third pixel circuit that is identical to the circuit shown in FIG. 6. For simplicity, the common elements of all circuits will be discussed in reference to those depicted in FIG. 6. With reference to FIG. 6 through FIG. 8D, 4 light emitting elements sequentially emit light during one frame period. Thus, one frame period can be divided into 4 sub-fields.

As shown in FIG. 6, the sixth and tenth transistors M6b and M10b in the first circuit receive the third light emitting control signal e3n and perform a switching operation. The sixth and tenth transistors M6b and M10b are NMOS transistors, and the seventh and ninth transistors M7b and M9b are PMOS transistors. The second pixel circuit is identical to the circuit shown in FIG. 6, but the sixth and tenth transistors M6b and M10b are PMOS transistors, and the seventh and ninth transistors M7b and M9b are NMOS transistors. In the third pixel circuit, which is identical to the first pixel circuit shown in FIG. 6, the sixth and tenth transistors M6b and M10b are NMOS transistors, and the seventh and ninth transistors M7b and M9b are PMOS transistors.

In addition, the first light emitting element OLED1b and the third light emitting element OLED3b of each pixel circuit receive a red data signal and emit light, whereas the second light emitting element OLED2b and the fourth light emitting element OLED4b of each pixel circuit receive a green data signal and emit light

Consequently, FIG. 8A shows a first sub-field among four sub-fields. As shown in FIG. 8A, in the first pixel circuit, the first light emitting element OLED1b connected to the sixth transistor M6b emits light. In the second pixel circuit, the second light emitting element OLED2b connected to the seventh transistor M7b emits light. In the third pixel circuit, the first light emitting element OLED1b connected to the sixth transistor M6b emits light. As a result, in the first sub-field, the first light emitting element OLED1b connected to the first pixel circuit and the third pixel circuit, emits light. The second light emitting element OLED2b connected to the second pixel circuit emits light, causing red and green light to be simultaneously emitted by means of the first and second light emitting elements OLED1b and OLED2b.

Further, FIG. 8B shows a second sub-field among four sub-fields. As shown in FIG. 8B, in the first pixel circuit, the fourth light emitting element OLED4b connected to the tenth transistor M10b emits light. In the second pixel circuit, the third light emitting element OLED3b connected to the ninth transistor M9b emits light. In the third pixel circuit, the fourth light emitting element OLED4b connected to the tenth transistor M10b emits light. As a result, in the second sub-field, the fourth light emitting element OLED4b connected to the first pixel circuit and the third pixel circuit, emits light. The third light emitting element OLED3b connected to the second pixel circuit emits light, causing red and green light to be simultaneously emitted by means of the fourth and fourth light emitting elements OLED3b and OLED4b.

In addition, FIG. 8C shows a third sub-field among four sub-fields. As shown in FIG. 8C, in the first pixel circuit, the second light emitting element OLED2b connected to the seventh transistor M7b emits light. In the second pixel circuit, the first light emitting element OLED1b connected to the sixth transistor M6b emits light. In the third pixel circuit, the second light emitting element OLED2b connected to the seventh transistor M7b emits light. As a result, in the third sub-field, red and green light to be simultaneously emitted by means of the first and second light emitting elements OLED1b and OLED2b.

Moreover, FIG. 8D shows a fourth sub-field among four sub-fields. As shown in FIG. 8D, in the first pixel circuit, the third light emitting element OLED3b connected to the ninth transistor M9b emits light. In the second pixel circuit, the fourth light emitting element OLED4b connected to the tenth transistor M10b emits light. In the third pixel circuit, the third light emitting element OLED3b connected to the ninth transistor M9b emits light. As a result, in the fourth sub-field, red and green light to be simultaneously emitted by means of the fourth and fourth light emitting elements OLED3b and OLED4b.

When only one color light is emitted at one sub-field, a color breakup occurs. In this embodiment, red and green lights are simultaneously emitted at respective sub-fields. In a total image display device, red, green, and blue light are emitted at respective sub-fields, thereby preventing a color breakup from occurring. The light emitting display shown in FIG. 2 operates in the same manner as above to prevent a color breakup from being occurred.

Although a few embodiments of the present invention have been shown and described, it would be appreciated by those skilled in the art that changes might be made in this embodiment without departing from the principles and spirit of the invention, the scope of which is defined in the claims and their equivalents.

In accordance with embodiments of the light emitting display of the present invention, since four light emitting elements are connected to one pixel circuit, the number of pixel circuits in a light emitting display is reduced. Thus, in comparison with the conventional light emitting display where one pixel circuit is connected to one light emitting element, a smaller number of elements is needed. As the number of pixel circuits is reduced, the numbers of scan lines, data lines, and light emitting control lines are reduced. Accordingly, a scan driver and a data driver can be embodied in a small size, thereby reducing unnecessary space. Further, as the amount of wiring is reduced, the aperture ratio of a light emitting display is improved. In addition, the order in which light emitting elements are light emitted is adjusted, thereby preventing color breakup of a light emitting display from occurring.

What is claimed is:

1. A light emitting display comprising:
a plurality of scan lines;
a plurality of data lines;
a plurality of first light emitting control lines;
a plurality of second light emitting control lines;
a plurality of third light emitting control lines; and
a plurality of pixels coupled to the plurality of data lines, the plurality of scan lines, and the plurality of emission control lines, each pixel comprising:
a first light emitting element;
a second light emitting element;
a third light emitting element;
a fourth light emitting element;
a drive circuit connected to and driving the first light emitting element, the second light emitting element, the third light emitting element, and the fourth light emitting element; and
a switch circuit assembly connected to the first light emitting element, the second light emitting element, the third light emitting element, and the fourth light emitting element, and the drive circuit for sequentially controlling driving of the first light emitting element, the second light emitting element, the third light emitting element, and the fourth light emitting element, the switch circuit assembly further comprising:
a first switch circuit for sequentially driving the first light emitting element and the second light emitting element according to a first light emitting control signal and a second light emitting control signal; and
a second switch circuit for sequentially driving the third light emitting element and the fourth light emitting element according to the second light emitting control signal and a third light emitting control signal.

2. The light emitting display as claimed in claim 1, wherein a first pixel and a second pixel among the plurality of pixels are arranged adjacent to each other and both receive a data signal through a first data line among the plurality of data lines,
wherein a first light emitting element and a second light emitting element of the first pixel are configured to light emit in a different order than are a first light emitting element and a second light emitting element of the second pixel, and
wherein a third light emitting element and a fourth light emitting element of the first pixel are configured to light emit in a different order than are a third light emitting element and a fourth light emitting element of the second pixel.

3. The light emitting display as claimed in claim 1, wherein the first light emitting control signal, the second light emitting control signal, and the third light emitting control signal are periodic signals each having a first period, a second period, a third period, and a fourth period,
wherein the first light emitting control signal and the second light emitting control signal maintain states different from each other, and repeat high and low states during respective periods, and
wherein the third light emitting control signal has a same state during the first period and the second period, and during the third period and the fourth period.

4. The light emitting display as claimed in claim 1, wherein the drive circuit comprises:
a first transistor for generating a current according to a first voltage corresponding to a data signal;
a second transistor for receiving a scan signal and transferring the data signal to the first transistor; and
a capacitor for storing the first voltage for a predetermined time.

5. The light emitting display as claimed in claim 4, wherein the first switch circuit comprises:
a third transistor for transferring a current according to the first light emitting control signal;
a fourth transistor for transferring the current transferred by the third transistor to the first light emitting element according to the third light emitting control signal; and
a fifth transistor for maintaining a state different from a state of the fourth transistor according to the third light emitting control signal and for transferring the current transferred by the third transistor to a second light emitting element, and
wherein the second switch circuit comprises:
a sixth transistor for transferring a current according to the second light emitting control signal;
a seventh transistor for transferring the current transferred by the sixth transistor to the third light emitting element according to the third light emitting control signal; and
an eighth transistor for maintaining a state different from a state of the eighth transistor according to the third light emitting control signal and for transferring the current transferred by the seventh transistor to the fourth light emitting element.

6. The light emitting display as claimed in claim 1, wherein the drive circuit comprises:
a first transistor for generating a current according to a first voltage corresponding to a data signal;
a second transistor for transferring the data signal corresponding to a first scan signal to the first transistor;
a first capacitor for storing the first voltage for a predetermined time;
a second capacitor for storing a threshold voltage of the second transistor;
a third transistor for diode-connecting the first transistor according to a second scan signal; and
a fourth transistor for applying voltage to a first electrode of the second capacitor according to a second scan signal.

7. The light emitting display as claimed in claim 6, wherein the first switch circuit comprises:
a fifth transistor for transferring a current according to the first light emitting control signal;
a sixth transistor for transferring the current transferred by the fifth transistor to the first light emitting element according to the third light emitting control signal; and
a seventh transistor for maintaining a state different from a state of the fifth transistor according to the third light emitting control signal and for transferring the current transferred by the fifth transistor to the second light emitting element, and
wherein the second switch circuit comprises:
an eighth transistor for transferring a current according to the second light emitting control signal;
a ninth transistor for transferring the current transferred by the eighth transistor to the third light emitting element according to the third light emitting control signal; and
a tenth transistor for maintaining a state different from the ninth transistor according to the third light emitting control signal and for transferring the current transferred by the eighth transistor to the fourth light emitting element.

8. The light emitting display as claimed in claim 6, wherein the second scan signal is a scan signal that is transferred to a scan line among the plurality of scan lines prior to another scan line among the plurality of scan lines to which the first scan signal is transferred.

9. The light emitting display as claimed in claim 1, further comprising a scan driver for transferring a scan signal and any of the first light emitting control signal, the second light emitting control signal, and the third light emitting control signal.

10. The light emitting display as claimed in claim 1, further comprising a data driver for transferring a data signal.

11. The light emitting display as claimed in claim 10, wherein the data driver sequentially outputs two data signals, each having different color information than the other, through one data line among the plurality of data lines.

12. The light emitting display as claimed in claim 1, wherein the first light emitting element, the second light emitting element, the third light emitting element, and the fourth light emitting element are configured to light emit sequentially during respective sub-fields, and a frame period comprises four sub-fields.

13. A pixel circuit comprising:
a first transistor for generating a current according to a first voltage corresponding to a data signal;
a second transistor for transferring the data signal corresponding to a scan signal to the first transistor;
a capacitor for storing the first voltage for a predetermined time;
a third transistor for transferring a current according to a first light emitting control signal;
a fourth transistor for transferring the current transferred by the third transistor to the first light emitting element according to a third light emitting control signal;
a fifth transistor for maintaining a state different from the fourth transistor according to the third light emitting control signal and for transferring the current transferred by the third transistor to a second light emitting element;
a sixth transistor for transferring a current according to a second light emitting control signal;
a seventh transistor for transferring the current transferred by the sixth transistor to a third light emitting element according to the third light emitting control signal; and
an eighth transistor for maintaining a state different from the seventh transistor according to the third light emitting control signal and for transferring the current transferred by the seventh transistor to a fourth light emitting element.

14. The pixel circuit as claimed in claim 13, wherein the first light emitting control signal, the second light emitting control signal, and the third light emitting control signal are periodic signals, each having a first period, a second period, a third period, and a fourth period,
wherein the first light emitting control signal and the second light emitting control signal maintain states different from each other, and repeat high and low states during respective periods, and
wherein the third light emitting control signal has a same state during the first period and the second period, and during the third period and the fourth period.

15. The light emitting display as claimed in claim 13, wherein the first light emitting element, the second light emitting element, the third light emitting element, and the fourth light emitting element are configured to light emit sequentially during respective sub-fields, and a frame period comprises four sub-fields.

16. A pixel circuit comprising:
a first transistor for generating a current according to a first voltage corresponding to a data signal;
a second transistor for transferring the data signal corresponding to a first scan signal to the first transistor;
a first capacitor for storing the first voltage for a predetermined time;
a second capacitor for storing a threshold voltage of the second transistor;
a third transistor for diode-connecting the first transistor according to a second scan signal;
a fourth transistor for transferring voltage to a first electrode of the second capacitor according to a second scan signal;
a fifth transistor for transferring a current according to a first light emitting control signal;
a sixth transistor for transferring the current transferred by the fifth transistor to the first light emitting element according to a third light emitting control signal;
a seventh transistor for maintaining a state different from a state of the sixth transistor according to the third light emitting control signal and for transferring the current transferred by the sixth transistor to a second light emitting element;
an eighth transistor for transferring the current according to a second light emitting control signal;
a ninth transistor for transferring the current transferred by the eighth transistor to a third light emitting element according to the third light emitting control signal; and
a tenth transistor for maintaining a state different from the ninth transistor according to the third light emitting control signal and for transferring the current transferred by the eighth transistor to a fourth light emitting element.

17. The pixel circuit as claimed in claim 16, wherein the second scan signal is a scan signal that is transferred to a scan line among the plurality of scan lines prior to another scan line among the plurality of scan lines to which the first scan signal is transferred.

18. The pixel circuit as claimed in claim 16, wherein the first light emitting control signal, the second light emitting control signal, and the third light emitting control signal are periodic signals, each having a first period, a second period, a third period, and a fourth period,
wherein the first light emitting control signal and the second light emitting control signal maintain states different from each other, and repeat high and low states during respective periods, and
wherein the third light emitting control signal has a same state during the first period and the second period, and during the third period and the fourth period.

19. The light emitting display as claimed in claim 16, wherein the first light emitting element, the second light emitting element, the third light emitting element, and the fourth light emitting element are configured to light emit sequentially during respective sub-fields, and a frame period comprises four sub-fields.
